(19) United States
(12) Patent Application Publication
(10) Pub. No.: US 2010/0052810 A1
(43) Pub. Date: Mar. 4, 2010

(54) ANTENNA CIRCUIT STRUCTURE AND ANTENNA STRUCTURE

(75) Inventors: YING-CHIEH CHUANG, TAIPEI (TW); CHING-CHUNG TANG, TAIPEI (TW)

Correspondence Address: ROSENBERG, KLEIN & LEE, 3458 ELLICOTT CENTER DRIVE-SUITE 101, ELLICOTT CITY, MD, 21043, US

(73) Assignee: ASUSTEK COMPUTER INC., TAIPEI (TW)

(21) Appl. No.: 12/502,538

(22) Filed: Jul. 14, 2009

(30) Foreign Application Priority Data
Aug. 26, 2008 (TW) 097132476

(51) Int. Cl. H03H 7/38; H01Q 1/50

(52) U.S. Cl. 333/32; 343/860

(57) ABSTRACT

An antenna circuit structure and an antenna structure are provided. The antenna structure includes an antenna circuit structure and a chip antenna. The antenna circuit structure includes a PCB and a feed-in point, an electrical point, a main circuit system and a matching circuit disposed on the PCB. Two electrical pins of the chip antenna are soldered in the feed-in point and the electrical point, respectively. The main circuit system is electrically connected to the feed-in point, and the matching circuit is electrically connected to the electrical point. Thus, the antenna structure can be easily calibrated to get preferable matching performance.

### BACKGROUND OF THE INVENTION

1. Filed of the Invention

The invention relates to an antenna circuit structure and an antenna structure and, more particularly, to an antenna circuit structure and an antenna structure having a matching circuit.

2. Description of the Related Art

With quick progress of wireless communication and miniaturization of communication products, embedded antennas need to be miniaturized in volume therewith to meet the demand. At present, chip antennas and planar antennas are widely used small antennas. The more popular chip antenna is a ceramic chip antenna using a low-temperature co-fired ceramics (LTCC) technique.

The chip antenna is provided for an assembly manufacturer as a part after manufactured. The assembly manufacturer only needs to solder the chip antenna on a printed circuit board (PCB). When the chip antenna is designed on the PCB, it should be calibrated to achieve the wireless radio frequency matching. The antenna may achieve the largest power transmission only when the impedance matches completely. This is more important to high frequency antennas.

FIG. 1 is a schematic diagram showing an antenna circuit structure 2 in the conventional technique. In FIG. 1, the antenna circuit structure 2 includes a PCB 4 as a base, and a feed-in point 6, an electrical point 8, a main circuit system 10 and a matching element 12 are disposed on the PCB 4.

Two electrical pins of the chip antenna 14 are electrically connected to the electrical point 8 and the feed-in point 6 in a soldering mode. The main circuit system 10 is the main function circuit of electronic equipment, and it has various initiative elements and passive elements. A matching element 12 is electrically connected between the feed-in point 6 and the main circuit system 10.

In the conventional technique, the matching element 12 is used to calibrate the chip antenna 14. Since the matching element 12 is adjacent to the posterior segment of the feed-in point 6, it is difficult to calibrate the chip antenna. FIG. 2 is a schematic diagram showing the relation of return loss and frequency of the chip antenna 14 having the conventional antenna circuit structure 2. As shown in FIG. 2, the antenna structure is designed for 2.4 GHz and its nearby frequency and used for short-distance wireless communication such as Bluetooth communication. However, the conventional matching mode is not easy to be used to calibrate, and this makes the frequency scope have some error.

Thus, the invention provides an antenna circuit structure and an antenna structure having preferable matching performance to solve the problems above.

### BRIEF SUMMARY OF THE INVENTION

The invention relates to an antenna structure and an antenna circuit structure having preferable matching performance. The antenna structure includes an antenna circuit structure and a chip antenna. The antenna circuit structure includes a printed circuit board (PCB), and a feed-in point, an electrical point, a main circuit system and a matching circuit are disposed on the PCB.

The feed-in point is disposed on the PCB on a same plane as the electrical point. Two electrical pins of the chip antenna are electrically connected to the feed-in point and the electrical point, respectively. The main circuit system is electrically connected to the feed-in point, and the matching circuit is electrically connected to the electrical point.

Thus, in the invention, the matching circuit is electrically connected to the electrical point via the antenna structure and the antenna circuit structure used in the antenna structure. Thus, the antenna structure can be easily calibrated to get preferable matching performance.

These and other features, aspects and advantages of the present invention will become better understood with regard to the following description, appended claims, and accompanying drawings.

### BRIEF DESCRIPTION OF THE DRAWINGS

FIG. 1 is a schematic diagram showing an antenna circuit structure in the conventional technique;

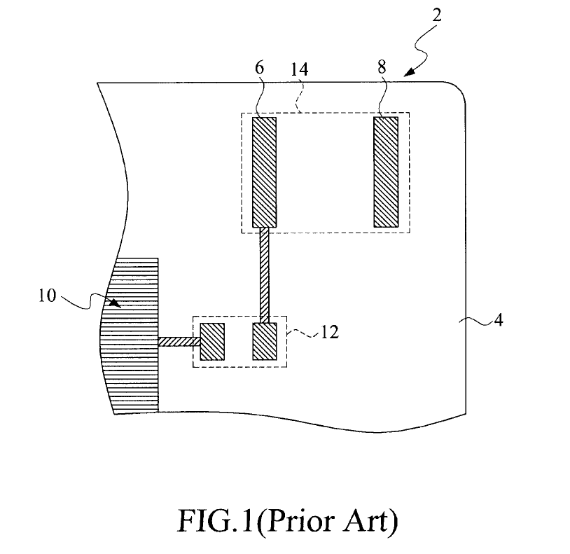

FIG. 2 is a schematic diagram showing the relation of return loss and frequency of the chip antenna having the conventional antenna circuit structure;

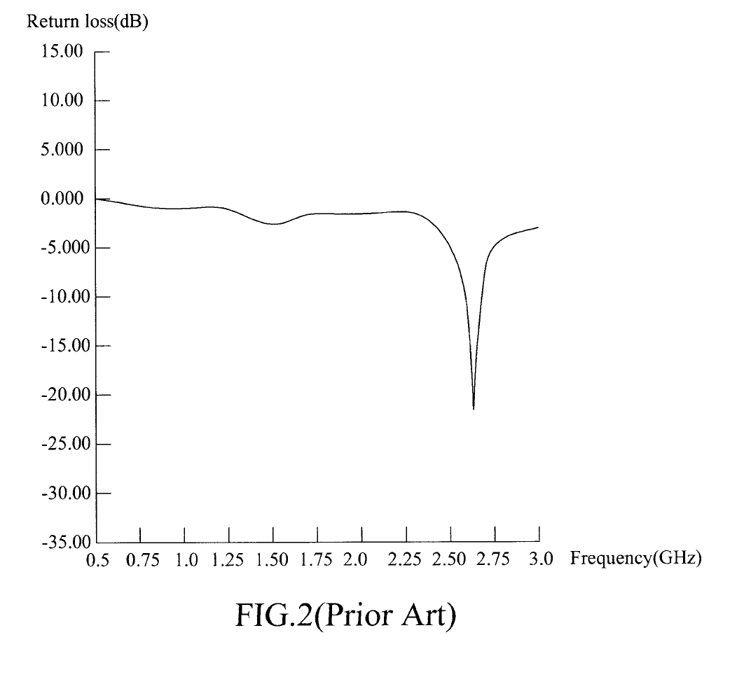

FIG. 3 is a schematic diagram showing the side view of the antenna structure in an embodiment of the invention;

FIG. 4 is a schematic diagram showing the front view of the antenna circuit structure in an embodiment of the invention;

FIG. 5 is a schematic diagram showing an arranging mode of the passive elements for composing the matching circuit in a first embodiment of the invention;

FIG. 6 is a schematic diagram showing an arranging mode of the passive elements for composing the matching circuit in a second embodiment of the invention;

FIG. 7 is a schematic diagram showing an arranging mode of the passive elements for composing the matching circuit in a third embodiment of the invention;

FIG. 8 is a schematic diagram showing the relation of return loss and frequency of the chip antenna using the antenna circuit structure in an embodiment of the invention; and

FIG. 9 is schematic diagram showing the matching circuit in another embodiment of the invention.

### DETAILED DESCRIPTION OF THE EMBODIMENTS

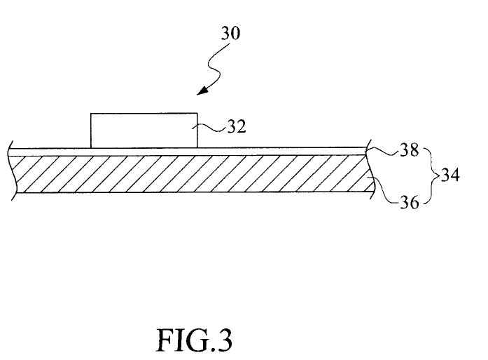

FIG. 3 is a schematic diagram showing the side view of the antenna structure 30 in an embodiment of the invention. As shown in FIG. 3, the invention relates to an antenna structure 30 and an antenna circuit structure 34 having preferable matching performance. The antenna structure 30 includes an antenna circuit structure 34 and a chip antenna 32. The antenna circuit structure 34 is divided into a PCB 36 and a circuit layer 38 disposed on the PCB 36. The chip antenna 32 is soldered on the circuit layer 38.

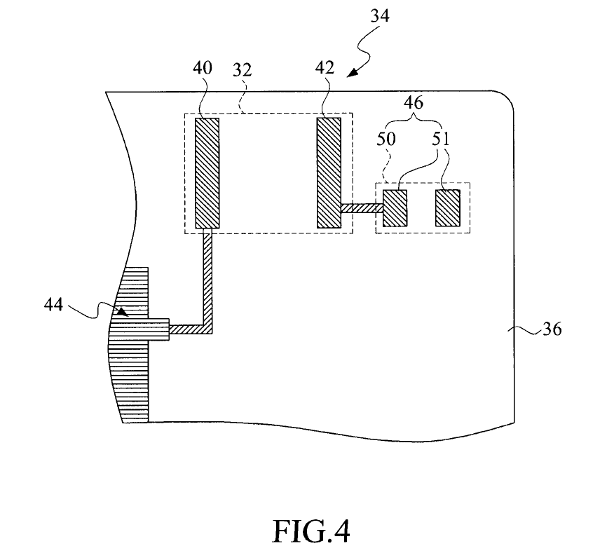

FIG. 4 is a schematic diagram showing the front view of the antenna circuit structure 34 in an embodiment of the invention. As shown in FIG. 4, the antenna circuit structure 34 includes a PCB 36 and a circuit layer 38 disposed on the PCB 36. The circuit layer 38 includes a feed-in point 40, an electrical point 42, a main circuit system 44 and related wiring 51 of the matching circuit 46.

The feed-in point 40 and the electrical point 42 are disposed on the same plane of the PCB 36. Two electrical pins of the chip antenna 32 are used to be electrically connected to the feed-in point 40 and the electrical point 42 in a soldering mode.

The main circuit system 44 is the main function circuit of electronic equipment, and it is electrically connected to the feed-in point 40. The matching circuit 46 is used to calibrate the antenna to achieve the wireless radio frequency matching. Thus, the impedance matches completely. The matching circuit 46 is electrically connected to the electrical point 42, and the matching circuit 46 may be composed of a plurality of passive elements 50 and the related wiring 51. As shown in the FIG. 4, the matching circuit 46 is composed of a passive element 50 soldered on the wiring 51. The passive element 50 may be a capacitor, an inductance or a resistor. All of them may be the passive elements 50. In addition, if a plurality of passive elements 50 are used, the passive elements 50 may have various arranging modes to compose the matching circuit 46, and the kinds of the passive elements 50 used together are not limited.

In addition, the main circuit system 44, the matching circuit 46, the electrical point 42 and the feed-in point 40 are electrically connected to each other via the circuit on the PCB 36. That is, the main circuit system 44, the matching circuit 46, the electrical point 42 and the feed-in point 40 all belong to the circuit layer 38. The two electrical pins of the chip antenna 32 are electrically connected to the electrical point 42 and the feed-in point 40 in a soldering mode.

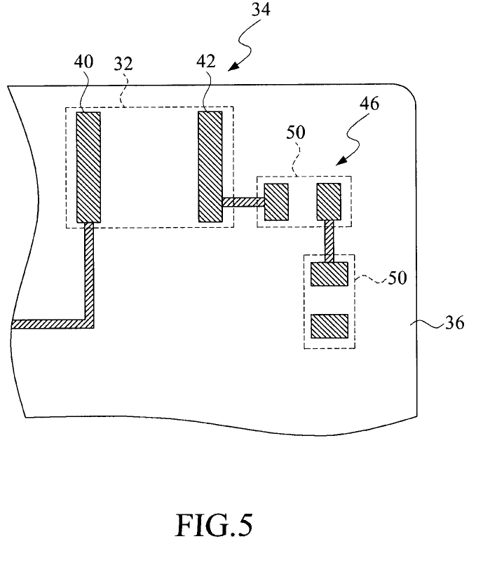

FIG. 5 is a schematic diagram showing an arranging mode of the passive elements 50 for composing the matching circuit 46 in a first embodiment of the invention. As in the above antenna circuit structure 34, the matching circuit 46 is composed of two passive elements 50 forming an L-shape structure. One passive element 50 is electrically connected to the electrical point 42 directly, and another passive element 50 is connected to the ground.

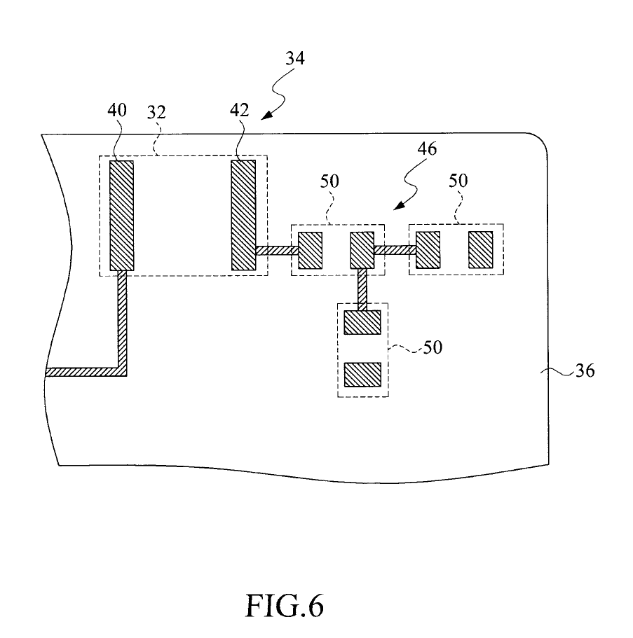

FIG. 6 is a schematic diagram showing an arranging mode of the passive elements 50 for composing the matching circuit 46 in a second embodiment of the invention. The matching circuit 46 also may be composed of three passive elements 50 forming a T-shaped structure. The passive element 50 at the side of the T-structure is electrically connected to the electrical point 42 directly, and another passive element 50 at the bottom of the T-shaped structure is connected to the ground.

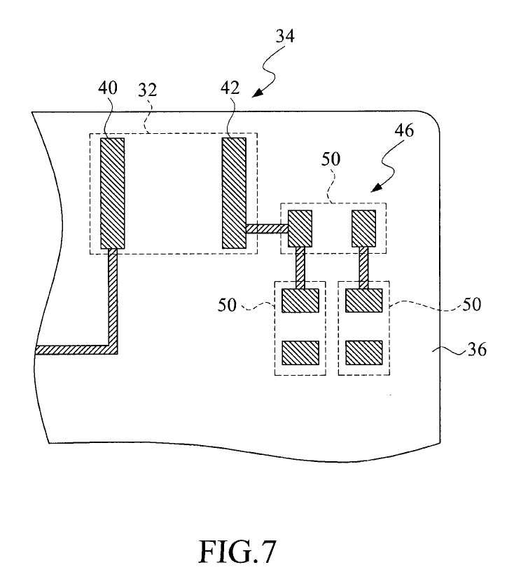

FIG. 7 is a schematic diagram showing an arranging mode of the passive elements 50 for composing the matching circuit 46 in a third embodiment of the invention. The matching circuit 46 is composed of three passive elements 50 forming a π-shaped structure. The transverse passive element 50 of the π-shaped structure is electrically connected to the electrical point 42 directly, and the other two passive elements 50 at the bottom of the π-shaped structure are connected to the ground.

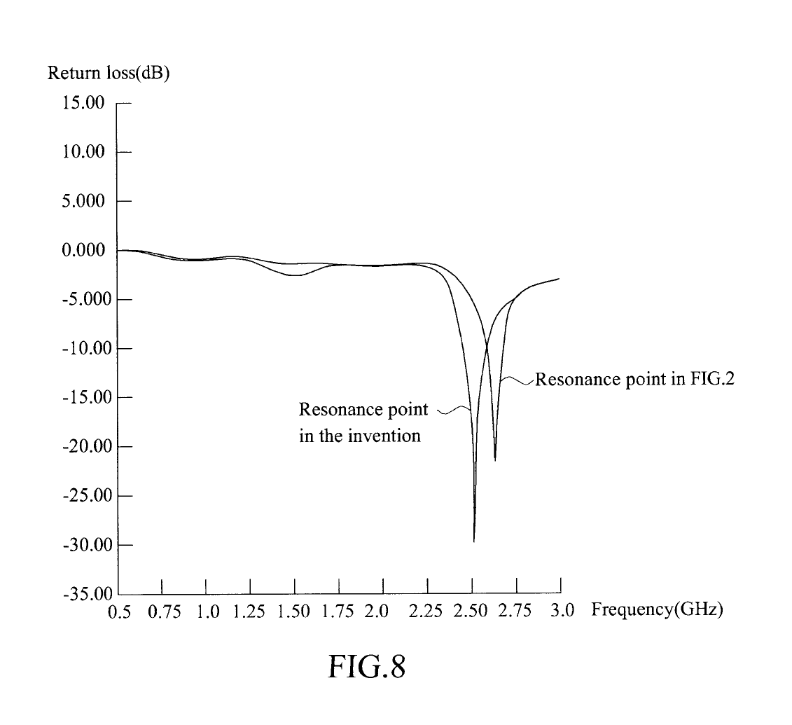

FIG. 8 is a schematic diagram showing the relation of return loss and frequency of the chip antenna 32 using the antenna circuit structure 34. It shows the relation of the return loss and the frequency generated by the antenna structure 30 in FIG. 6. The antenna structure 30 is designed for 2.4 GHz and its nearby frequency and used for short-distance wireless communication such as the Bluetooth communication. Since the matching mode is easy to be used to calibrate, the frequency scope of in invention is finer than the frequency scope in the conventional technique.

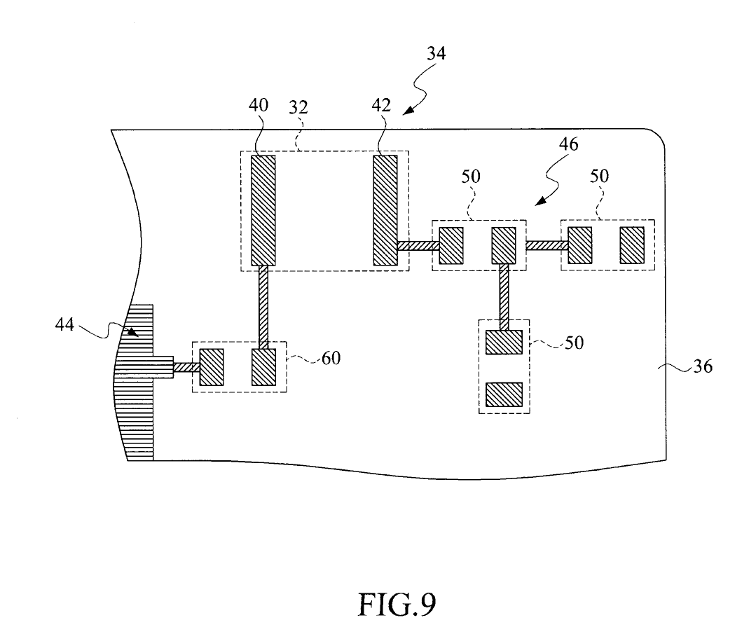

FIG. 9 is another schematic diagram showing the matching circuit 46 in another embodiment of the invention. As shown in FIG. 9, except for the antenna circuit structure 34 in FIG. 4, a matching element 60 also may be disposed. The matching element 60 is disposed on the PCB 36, and the main circuit system 44 is electrically connected to the feed-in point 40 via the matching element 60. FIG. 9 shows an embodiment with the matching circuit 46 in FIG. 6 and a matching element 60.

With the help of the matching circuit 46 in the invention, even the conventional matching element 60 electrically connected to the feed-in point 40 is assembled, the disadvantage of the conventional technique that the chip antenna is hard to be calibrated also may be avoided.

Therefore, in the invention, the matching circuit 46 is electrically connected to the electrical point 42 via the antenna structure 30 and the antenna circuit structure 34 used in the antenna structure 30. Thus, the antenna structure can be easily calibrated to get the preferable matching performance.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. An antenna circuit structure matching a chip antenna, comprising:
a printed circuit board (PCB);
a feed-in point disposed on the PCB;
an electrical point disposed on the PCB, wherein the feed-in point and the electrical point are used to be electrically connected to two electrical pins of the chip antenna;
a main circuit system disposed on the PCB and electrically connected to the feed-in point; and
a matching circuit disposed on the PCB and electrically connected to the electrical point.

2. The antenna circuit structure according to claim 1, wherein the matching circuit is composed of a plurality of passive elements.

3. The antenna circuit structure according to claim 2, wherein the passive elements are selected from the group consisting of a capacitor, an inductance and a resister.

4. The antenna circuit structure according to claim 2, wherein the matching circuit is composed of two passive elements forming an L-shaped structure.

5. The antenna circuit structure according to claim 2, wherein the matching circuit is composed of three passive elements forming a T-shaped or π-shaped structure.

6. The antenna circuit structure according to claim 1, wherein the antenna circuit structure further comprises a matching element disposed on the PCB, and the main circuit system is electrically connected to the feed-in point via the matching element.

7. The antenna circuit structure according to claim 1, wherein the main circuit system, the matching circuit, the electrical point, the feed-in point are electrically connected to each other via a circuit on the PCB, and the electrical pins of the chip antenna are electrically connected to the electrical point and the feed-in point in a soldering mode.
